(19) United States
(12) Patent Application Publication
(10) Pub. No.: US 2021/0286462 A1
(43) Pub. Date: Sep. 16, 2021

(54) TOUCH KEYBOARD

(71) Applicant: PIXART IMAGING INC., HSIN-CHU (TW)

(72) Inventors: SUNG-HAN WU, HSIN-CHU (TW); CHE-CHIA HSU, HSIN-CHU (TW)

(21) Appl. No.: 17/074,697

(22) Filed: Oct. 20, 2020

(30) Foreign Application Priority Data
Mar. 16, 2020 (CN) 202010181517.0

(51) Int. Cl. G06F 3/041; G06F 3/044; H03K 17/96

(52) U.S. Cl. CPC G06F 3/0418; H03K 17/962; G06F 3/044

(57) ABSTRACT

A touch keyboard includes a key set, a capacitive touch sensor, and a pressure sensing circuit. The capacitive touch sensor is coupled to the key set and is configured to generate a sensing capacitance. The pressure sensing circuit is coupled to the capacitive touch sensor, configured to generate a pressure sensing value, and specifically includes a cancellation circuit. The cancellation circuit is configured to generate a cancellation signal, and enable a capacitor voltage converter in the pressure sensing circuit to output an analog voltage signal according to the sensing signal being added with the cancellation signal, and the content of the sensing signal is the sensing capacitance generated by the capacitive touch sensor.

### CROSS-REFERENCE TO RELATED PATENT APPLICATION

This application claims the benefit of priority to China Patent Application No. 202010181517.0, filed on Mar. 16, 2020 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a touch keyboard, and more particularly to a touch keyboard capable of improving sensitivity.

### BACKGROUND OF THE DISCLOSURE

Compared with traditional keyboards, a touch keyboard integrates a touch panel into a keyboard, such that the keyboard can be provided with touch functions. For example, users can control cursor movement by sliding a finger on a surface of the keyboard. In addition, most existing touch panels on the market use capacitive touch sensors. Touch keyboards including capacitive touch sensors utilize different sensing capacitances generated by the capacitive touch sensors while the user presses and touches the key sets, to determine whether the user is pressing or touching the key set.

However, the sensing capacitance of the capacitive touch sensor from the user pressing the key set is much greater than that from the user touching the key set. Therefore, when two applications of the capacitive touch sensor, such as a press on key and a touch on keyboard (TOK), are both present in a single device, overflow conditions may easily occur for existing capacitor voltage converters, so that the sensing capacitance cannot be correctly converted to a corresponding voltage value. In other words, a touch keyboard needs to have a large detection range in order to detect the press on key and the touch on keyboard at the same time. This also signifies that the detection range is very important for the sensitivity of the touch keyboard. Therefore, there is an urgent need in the art for a touch keyboard capable of preventing the capacitor voltage converter from overflowing as a result of receiving an excessively large sensing capacitance.

### SUMMARY OF THE DISCLOSURE

In response to the above-referenced technical inadequacies, one aspect of the present disclosure provides a touch keyboard including a key set, a capacitive touch sensor, and a pressure sensing circuit. The capacitive touch sensor is coupled to the key set and is configured to generate a sensing capacitance. The pressure sensing circuit is coupled to the capacitive touch sensor, configured to generate a pressure sensing value, and includes a converter, a cancellation circuit, an analog-to-digital converter (ADC), and a digital signal processor. The converter is coupled to an input pin, configured to receive a sensing signal provided from the input pin, and output an analog voltage signal. The cancellation circuit is coupled between the converter and the input pin, configured to generate a cancellation signal, and enable the converter to output the analog voltage signal according to the sensing signal being added with the cancellation signal. The ADC is coupled to the converter and configured to convert the analog voltage signal into a digital voltage signal. The digital signal processor is coupled to the ADC and configured to generate the pressure sensing value corresponding to the sensing signal according to the digital voltage signal.

In another aspect, the present disclosure further provides a touch keyboard, which includes a key set, a capacitive touch sensor, and a pressure sensing circuit. The capacitive touch sensor is coupled to the key set and is configured to generate a sensing capacitance. The pressure sensing circuit is coupled to the capacitive touch sensor, configured to generate a pressure sensing value, and includes a converter, an analog-to-digital converter (ADC), a cancellation circuit, and a digital signal processor. The converter is coupled to an input pin, configured to receive a sensing signal provided from the input pin, and output an analog voltage signal. The ADC is coupled to the converter and configured to convert the analog voltage signal into a digital voltage signal. The cancellation circuit is coupled between the converter and the ADC, configured to generate a cancellation signal, and enable the ADC to output the digital voltage signal according to the analog voltage signal after being subtracted with the cancellation signal. The digital signal processor is coupled to the ADC and configured to generate the pressure sensing value corresponding to the sensing signal according to the digital voltage signal.

In another aspect, the present disclosure further provides a touch keyboard, which includes a key set, a capacitive touch sensor, and a pressure sensing circuit. The capacitive touch sensor is coupled to the key set and is configured to generate a sensing capacitance. The pressure sensing circuit is coupled to the capacitive touch sensor, and configured to generate a pressure sensing value, and includes a converter, a suppression circuit, an analog-to-digital converter, and a digital signal processor. The converter is coupled to an input pin, configured to receive a sensing signal provided from the input pin, and output an analog voltage signal. The suppression circuit is coupled between the converter and the input pin, configured to suppress the sensing signal according to a preset parameter, then provide the suppressed sensing signal to the converter, and enable the converter to output the analog voltage signal according to the suppressed sensing signal. The ADC is coupled to the converter and configured to convert the analog voltage signal into a digital voltage signal. The digital signal processor is coupled to the ADC and configured to generate the pressure sensing value corresponding to the sensing signal according to the digital voltage signal.

Preferably, the above-mentioned converters are all capacitor voltage converters, and the content of the sensing signal is the sensing capacitance generated by the capacitive touch sensor. In addition, the input pin is used to couple the pressure sensing circuit to an output terminal of the capacitive touch sensor.

In yet another aspect, the present disclosure further provides a touch keyboard, which includes a key set, a capacitive touch sensor, and a pressure sensing circuit. The capacitive touch sensor is coupled to the key set and is configured to generate a sensing capacitance. The pressure sensing circuit is coupled to the capacitive touch sensor, configured to generate a pressure sensing value, and includes a converter and a cancellation circuit. The converter is coupled to an input pin, configured to receive a capacitance sensing signal provided from the input pin, and outputs a circuit signal corresponding to a pressure value sensed by the capacitance sensing signal. The cancellation circuit is coupled between the converter and the input pin, configured to generate a cancellation signal, and enables the converter to output the circuit signal according to the capacitance sensing signal being added with the cancellation signal.

Preferably, the circuit signal is a voltage signal, and a voltage value of the voltage signal is proportional to the pressure value sensed by the capacitance sensing signal. In addition, the voltage signal is an analog voltage signal, and the converter can be coupled to an analog-to-digital converter, and configured to convert the analog voltage signal into a digital voltage signal. The pressure sensing circuit further includes a digital signal processor coupled to the ADC and configured to generate the pressure sensing value corresponding to the capacitance sensing signal according to the digital voltage signal.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic functional block diagram of a touch keyboard according to a first embodiment of the present disclosure.

FIG. 2 is a schematic circuit diagram of a converter and a cancellation circuit of FIG. 1 according to a first preferred embodiment.

FIG. 3 is a schematic circuit diagram of the converter and the cancellation circuit of FIG. 1 according to a second preferred embodiment.

FIG. 4 is a schematic functional block diagram of a touch keyboard according to a second embodiment of the present disclosure.

FIG. 5 is a schematic circuit diagram of a converter and a cancellation circuit of FIG. 4 according to a first preferred embodiment.

FIG. 6 is a schematic circuit diagram of the converter and the cancellation circuit of FIG. 4 according to a second preferred embodiment.

FIG. 7 is a schematic circuit diagram of the converter and the cancellation circuit of FIG. 4 according to a third preferred embodiment.

FIG. 8 is a schematic functional block diagram of a touch keyboard according to a third embodiment of the present disclosure.

FIG. 9 is a schematic circuit diagram of a converter and a suppression circuit of FIG. 8 according to a first preferred embodiment.

FIG. 10 is a schematic circuit diagram of the converter and the suppression circuit of FIG. 8 according to a second preferred embodiment.

FIG. 11 is a schematic circuit diagram of the converter and the suppression circuit of FIG. 8 according to a third preferred embodiment.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way.

Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

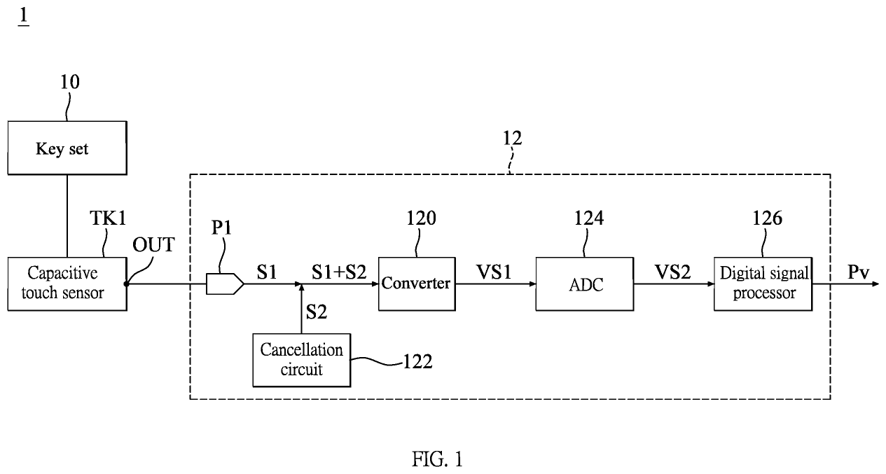

Reference is made to FIG. 1, which is a functional block diagram of a touch keyboard according to a first embodiment of the present disclosure. The touch keyboard 1 includes a key set 10, a capacitive touch sensor TK1, and a pressure sensing circuit 12. The capacitive touch sensor TK1 is coupled to the key set 10 and is configured to generate a sensing capacitance. It should be noted that the present disclosure does not limit the specific implementation of the key set 10 and the capacitive touch sensor TK1, and for the convenience of the following description, the capacitive touch sensor TK1 of the present disclosure only uses an example with a quantity of 1, but it also not intended to limit the present disclosure. In short, since the operation principles of the key set 10 and the capacitive touch sensor TK1 are known to those skilled in the art, the details related to the key set 10 and the capacitive touch sensor TK1 will not be repeated here.

In addition, the pressure sensing circuit 12 is coupled to the capacitive touch sensor TK1, configured to generate a pressure sensing value Pv, and includes a converter 120, a cancellation circuit 122, an analog-to-digital converter (ADC) 124, and a digital signal processor 126. The converter 120 is coupled to an input pin P1, and is configured to receive a sensing signal S1 provided from the input pin P1, and output an analog voltage signal VS1. The cancellation circuit 122 is coupled between the converter 120 and the input pin P1, configured to generate a cancellation signal S2, and enable the converter 120 to output the analog voltage signal VS1 according to the sensing signal S1 being added with the cancellation signal S2. The ADC 124 is coupled to the converter 120 and configured to convert the analog voltage signal VS1 into a digital voltage signal VS2. The digital signal processor 126 is coupled to the ADC 124 and configured to generate the pressure sensing value Pv corresponding to the sensing signal S1 according to the digital voltage signal VS2.

However, since operating principles of the ADC 124 and the digital signal processor 126 are already known to those skilled in the art, details related to the ADC 124 and the digital signal processor 126 will not be repeated here. According to the teachings of the above descriptions, those skilled in the art should understand that content of the sensing signal S1 is a sensing capacitance generated by the capacitive touch sensor TK1, and the input pin P1 is used to couple the pressure sensing circuit 12 to an output terminal OUT of the capacitive touch sensor TK1. Next, the implementation of the converter 120 and the cancellation circuit 122 will be further described below.

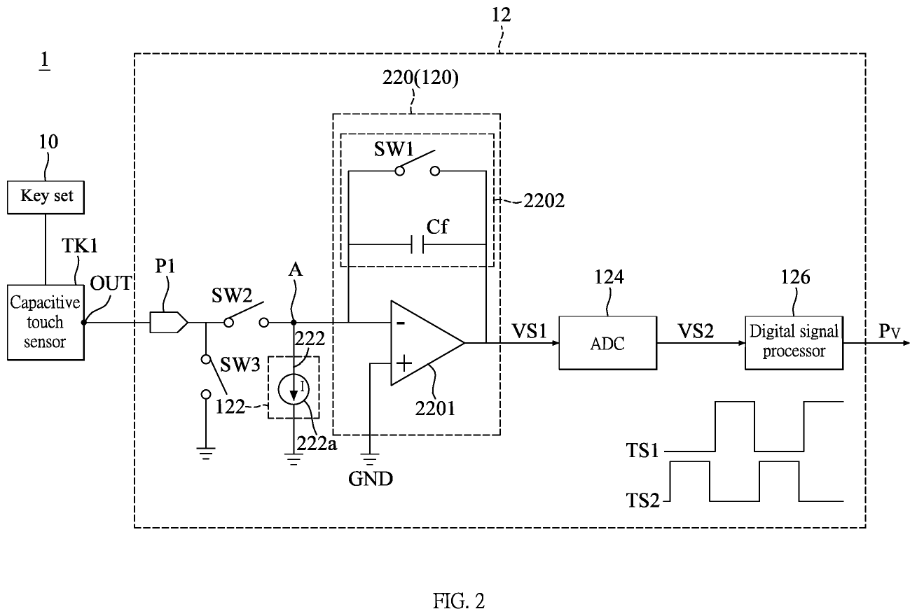

Reference is made to FIG. 2, which is a circuit diagram of a converter 120 and a cancellation circuit 122 of FIG. 1 according to a first preferred embodiment. As shown in FIG. 2, the converter 120 may be, for example, a capacitor voltage converter 220 and includes an operational amplifier 2201 and a negative feedback circuit 2202. The operational amplifier 2201 has an inverting input terminal P1 coupled to a node A between the input pin P1 and the cancellation circuit 122, a non-inverting input terminal coupled to a ground voltage GND, and an output terminal coupled to the ADC 124. In addition, the negative feedback circuit 2202 is coupled between the inverting input terminal of the operational amplifier 2201 and the output terminal of the operational amplifier 2201, and the negative feedback circuit 2202 is composed of a first capacitor Cf and a first switch SW1 connected in parallel with each other. In the present embodiment, the first switch SW1 is controlled by the first control signal TS1 to be turned on or off.

However, since the operating principles of the capacitor voltage converter 220 are already known to those skilled in the art, details related to the operational amplifier 2201 and the negative feedback circuit 2202 will not be repeated here. As mentioned above, when the sensing capacitance generated by the capacitive touch sensor TK1 is too large, overflow conditions are easily occurred for the capacitor voltage converter 220, causing the sensing capacitance to not be able to be correctly converted into the corresponding voltage value. That is, the capacitor voltage converter 220 cannot effectively output the analog voltage signal VS1 corresponding to the sensing capacitance. Therefore, a technical core of the first embodiment of the present disclosure is to additionally add the cancellation circuit 122 between the input pin P1 and the capacitor voltage converter 220 to enable the sensing capacitance generated by the capacitive touch sensor TK1, that is, the sensing signal S1 can be attenuated to avoid the capacitor voltage converter 220 in the touch keyboard 1 from overflowing due to receiving an excessively large sensing capacitance, and allows the capacitor voltage converter 220 to effectively output the analog voltage signal VS1 corresponding to the attenuated sensing capacitance.

It is worth mentioning that the present disclosure does not limit the specific implementation of attenuating the sensing capacitance, that is, the sensing signal S1. Those skilled in the art should be able to design according to actual needs or applications. It should be noted that the so-called “attenuating the sensing capacitance” may refer to achieving the attenuation effect in a quantitative manner or a non-quantitative manner, but the present disclosure is not limited thereto. In a word, according to the teachings of the above descriptions and through the existing technology, those skilled in the art should understand that the capacitor voltage converter 220 in FIG. 2 can also be regarded as a discrete-type circuit design. Therefore, the pressure sensing circuit 12 in FIG. 2 can further include a second switch SW2 and a third switch SW3.

In the present embodiment, the second switch SW2 is coupled between the input pin P1 and the node A, and is controlled by the second control signal TS2 to be turned on or off In addition, the third switch SW3 is coupled between the input pin P1 and the ground voltage GND, and is controlled by the first control signal TS1 to be turned on or off That is, the first switch SW1 and the third switch SW3 are controlled to be turned on simultaneously by the first control signal TS1, and on-times of the first switch SW1 and the third switch SW3 controlled by the first control signal TS1 are staggered with on-times of the second switch SW2 controlled by the second control signal TS2. As shown in FIG. 2, operation timings of the first control signal TS1 and the second control signal TS2 are partially illustrated, and thus the details will not be repeated here.

However, to further explain how to attenuate the sensing capacitance, that is, the sensing signal S1, the present disclosure provides the following specific implementation. As shown in FIG. 2, the cancellation circuit 122 can be, for example, a branch connection 222, which is coupled between the node A and the ground voltage GND, and is configured to reduce the sensing capacitance generated by the capacitive touch sensor TK1, and enable the capacitor voltage converter 220 to output the analog voltage signal VS1 according to the reduced sensing capacitance. In this embodiment, a degree of attenuation caused by the branch capacitor 222 to the sensing capacitance can be determined by a preset parameter, or determined according to the current operating environment of the pressure sensing circuit 1 (e.g., operating temperature, average sensing capacitance, and the like.) However, the present disclosure is not limited thereto.

In addition, if it is considered that an effect of attenuation is achieved in a quantitative manner, the branch wiring 222 can further include a constant current source circuit 222a. The constant current source circuit 222a is configured to, in response to the second control signal TS2 controlling the second switch SW2 to be turned on, attenuate the sensing capacitance generated by the capacitive touch sensor TK1 according to a preset parameter to enable the capacitor voltage converter 220 to output the analog voltage signal VS1 according to the attenuated sensing capacitance. It is worth mentioning that since operating principles of the constant current source circuit 222a is also known to those skilled in the art, details of the constant current source circuit 222a will not be repeated here, and the so-called “preset parameter” can be a constant current value I provided by the constant current source circuit 222a. Therefore, when the constant current value I become larger, the degree of attenuation experienced by the sensing capacitance is greater, but the present disclosure does not limit the specific implementation of the constant current value I.

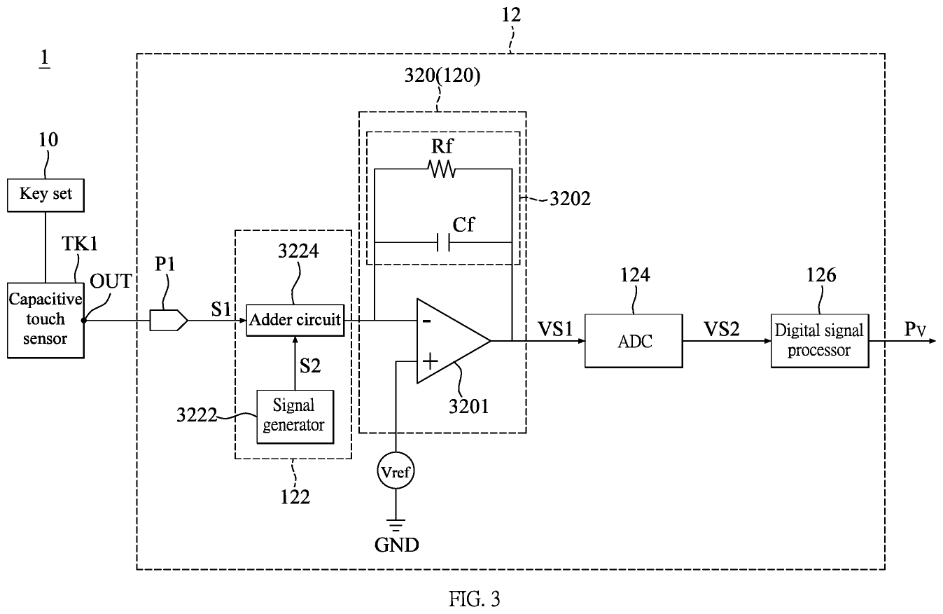

It can be seen that the touch keyboard 1 according to the first embodiment of the present disclosure can not only use the constant current source circuit 222a to quantitatively attenuate the sensing capacitance generated by the capacitive touch sensor TK1, but also the touch keyboard 1 of the first embodiment of the present disclosure can also use time differences of the first switch SW1, the second switch SW2, and the third switch SW3 to be staggered controlled to avoid sudden variation of the first capacitor Cf in the capacitor voltage converter 220, thereby making the voltage converter 220 to output a more stable analog voltage signal VS1. It should be noted that the above-mentioned implementation of the constant current source circuit 222a is only an example, and it is not intended to limit the present disclosure. In addition, the capacitor voltage converter 220 can also be considered as a circuit design having a continuous type structure. Therefore, reference is made to FIG. 3, FIG. 3 is a circuit diagram of the converter 120 and the cancellation circuit 122 of FIG. 1 according to a second preferred embodiment.

Compared to the capacitor voltage converter 220 of FIG. 2, the capacitor voltage converter 320 of FIG. 3 includes an operational amplifier 3201 and a negative feedback circuit 3202. An inverting input terminal of the operational amplifier 3201 is coupled to the input pin P1 through an adder circuit 3224, a non-inverting input terminal of the operational amplifier 3201 is coupled to a reference voltage Vref, and an output terminal of the operational amplifier 3201 is coupled to the ADC 124. In addition, the negative feedback circuit 3202 is coupled between the inverting input terminal of the operational amplifier 3201 and the output terminal of the operational amplifier 3201, and the negative feedback circuit 3202 is composed of a first capacitor Cf and a first resistor Rf connected in parallel with each other. However, since operating principles of the capacitor voltage converter 320 are already known to those skilled in the art, details related to the operational amplifier 3201 and the negative feedback circuit 3202 will not be repeated here.

To further explain how to attenuate the sensing capacitance, that is, the sensing signal S1, the present disclosure provides another specific implementation. As shown in FIG. 3, the cancellation circuit 122 can include a signal generator 3222 and an adder circuit 3224. The signal generator 3222 is configured to generate the cancellation signal S2, and a polarity of the cancellation signal S2 generated by the signal generator 3222 is opposite to a polarity of the sensing capacitance, i.e., the sensing signal S1 generated by the capacitive touch sensor TK1. In addition, the adder circuit 3224 is configured to add the sensing capacitance generated by the capacitive touch sensor TK1 to the cancellation signal S2 generated by the signal generator 3222, and then provide the sensing capacitance added with the cancellation signal S2 to the capacitor voltage converter 320. It should be noted that the above-mentioned implementation of the adder circuit 3224 is only an example, and it is not intended to limit the present disclosure.

For example, in other embodiments, when the polarity of the cancellation signal S2 generated by the signal generator 3222 is the same as the polarity of the sensing capacitance generated by the capacitive touch sensor TK1, the adder circuit 3224 can be replaced by a subtractor circuit (not shown in FIG. 3). It can be seen that the subtractor circuit is then configured to subtract the sensing capacitance generated by the capacitive touch sensor TK1 from the cancellation signal S2 generated by the signal generator 3222, and then provide the sensing capacitance that is subtracted by the cancellation signal S2 to converter 320. In other words, the calculation manner used by the cancellation circuit 122 to attenuate the sensing capacitance, such as addition or subtraction, may be determined by the polarity of the cancellation signal S2 generated by the signal generator 3222, or according to current operational requirements of the pressure sensing circuit 12, but the present disclosure is not limited thereto.

In other words, the touch keyboard 1 according to the second embodiment of the present disclosure can use the cancellation signal S2 generated by the signal generator 3222 to attenuate the sensing capacitance generated by the capacitive touch sensor TK1, thereby avoiding the capacitor voltage converter 320 from overflowing due to receiving an excessively large sensing capacitance, and allowing the capacitor voltage converter 320 to output the analog voltage signal VS1 corresponding to the attenuated sensing capacitance. In practice, the signal generator 3222 can be, for example, a digital-to-analog converter, but the present disclosure is not limited thereto, and the signal generator 3222 can be programmable designed to determine a magnitude of the cancellation signal S2 according to a magnitude of the sensing capacitance generated by the capacitive touch sensor TK1. In short, the present disclosure does not limit the specific implementation of attenuating the sensing capacitance.

Similarly, if it is still considered that an effect of attenuation is achieved in a quantitative manner, in other embodiments, the magnitude of the cancellation signal S2 generated by the signal generator 3222 can be the same as the magnitude of the sensing capacitance of the capacitive touch sensor TK1 that is not pressed. In this way, the touch keyboard 1 according to the second embodiment of the present disclosure can not only use the cancellation signal S2 generated by the signal generator 3222 to completely cancel the sensing capacitance generated by the capacitive touch sensor TK1 that is not pressed but the touch keyboard 1 according to the second embodiment of the present disclosure can also use the cancellation signal S2 to quantify the sensing capacitance generated by the capacitive touch sensor TK1 due to pressing thereon, thereby avoiding the capacitor voltage converter 320 from overflowing due to receiving an excessively large sensing capacitance.

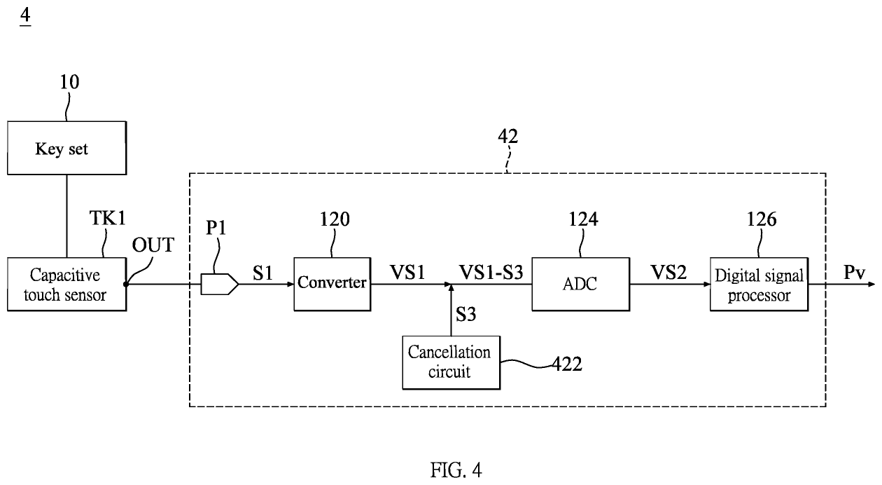

It can be seen that, the touch keyboard 1 of FIG. 2 and FIG. 3 can both attenuate the sensing capacitance through the cancellation circuit 122 before the sensing capacitance, that is, the sensing signal S1, generated by the capacitive touch sensor TK1 is input to the converter 120, that is, the capacitor voltage converters 220 and 320, thereby preventing the converter 120 from overflowing due to receiving an excessively large sensing capacitance, and allow the converter 120 to effectively output the analog voltage signal VS1 corresponding to the attenuated sensing capacitance. However, if the probability that the converter 120 will overflow is not taken into account first, in other embodiments, the cancellation circuit 122 can be changed to attenuate the analog voltage signal VS1 after the converter 120 outputs the analog voltage signal VS1 according to the sensing capacitance generated by the capacitive touch sensor TK1, to enable the ADC 124 to output the digital voltage signal VS2 according to the attenuated analog voltage signal VS1. Therefore, reference is made to FIG. 4, FIG. 4 is a functional block diagram of a touch keyboard 4 according to a second embodiment of the present disclosure, and some components in FIG. 4 that are the same as or similar to those in FIG. 1 are represented by the same or similar reference numerals, so the details are not described in detail.

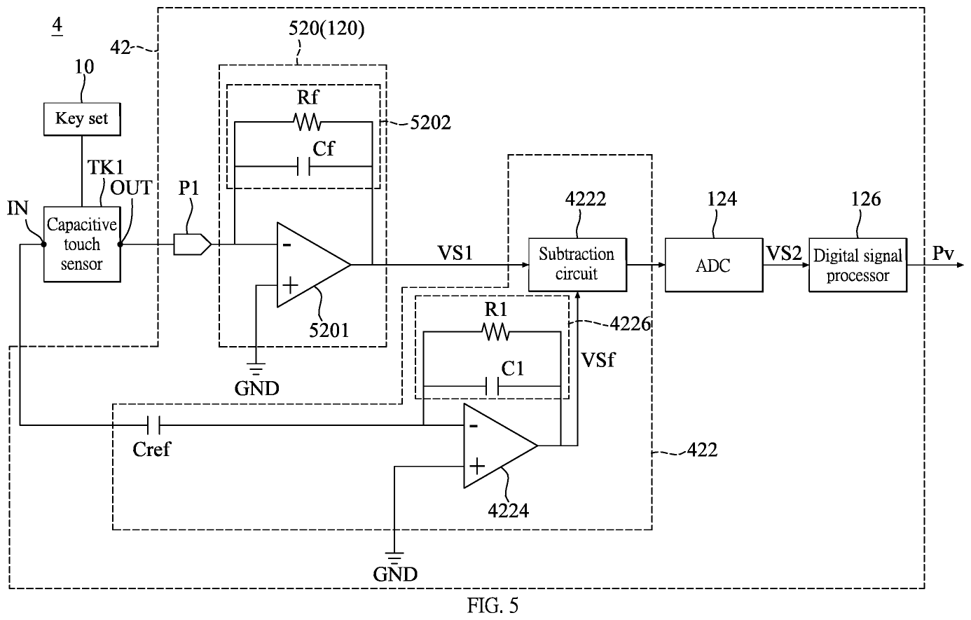

In short, compared to the cancellation circuit 122 of FIG. 1, the cancellation circuit 422 of FIG. 4 is coupled between the converter 120 and the ADC 124 to generate the cancellation signal S3, and enable the ADC 124 to output the digital voltage signal VS2 according to the analog voltage signal VS1 that is subtracted by the cancellation signal S3. Reference is made to FIG. 5, which is a circuit diagram of a converter 120 and a cancellation circuit 422 of FIG. 4 according to a first preferred embodiment.

As shown in FIG. 5, the converter 120 can be, for example, a capacitor voltage converter 520 and includes an operational amplifier 5201 and a negative feedback circuit 5202. An inverting input terminal of the operational amplifier 5201 is coupled to the input pin P1, a non-inverting input terminal of the operational amplifier 5201 is coupled to the ground voltage GND, and an output terminal of the operational amplifier 5201 is coupled to the ADC 124 through a subtractor circuit 4222. In addition, the negative feedback circuit 5202 is coupled between the inverting input terminal of the operational amplifier 5201 and the output terminal of the operational amplifier 5201. The negative feedback circuit 5202 is composed of a first capacitor Cf and a first resistor Rf connected in parallel with each other. However, since operating principles of the capacitor voltage converter 520 are already known to those skilled in the art, details related to the operational amplifier 5201 and the negative feedback circuit 5202 will not be repeated here. Furthermore, the cancellation circuit 422 of FIG. 5 can include a subtractor circuit 4222, an operational amplifier 4224, a negative feedback circuit 4226, and a reference capacitor Cref.

The subtractor circuit 4222 is coupled between the output terminal of the operational amplifier 5201 and the ADC 124. An inverting input terminal of the operational amplifier 4224 is coupled to an input terminal IN of the capacitive touch sensor TK1, a non-inverting input terminal of the operational amplifier 4224 is coupled to the ground voltage GND, and an output terminal of the operational amplifier 4224 is coupled to the subtractor circuit 4222. The negative feedback circuit 4226 is coupled between the inverting input terminal of the operational amplifier 4224 and the output terminal of the operational amplifier 4224, and the negative feedback circuit 4226 is composed of a capacitor C1 and a resistor R1 connected in parallel with each other. The reference capacitor Cref is coupled between the inverting input terminal of the operational amplifier 4224 and the input terminal IN of the capacitive touch sensor TK1.

It should be understood that the operational amplifier 5201 and the negative feedback circuit 4226 can be regarded as the capacitor voltage converter 520 on another branch connection. Therefore, the above-mentioned “capacitor C1 and resistor R1” can refer to the capacitor and the resistor being the same as the first capacitor Cf and the first resistor Rf, respectively, but the present disclosure is not limited thereto. In short, the present disclosure does not limit the specific implementation of the capacitor voltage converter 520 on the branch connection, those skilled in the art should be able to design the operational amplifier 5201 and the negative feedback circuit 4226 according to actual needs or applications.

According to the teachings of the foregoing descriptions, those skilled in the art should understand that the operational amplifier 4224, the negative feedback circuit 4226, the reference capacitor Cref, and the capacitor voltage converter 520 can be commonly disposed on the same chip substrate, and when a driver signal (not shown in FIG. 5) is input to the input terminal IN of the capacitive touch sensor TK1, the capacitive touch sensor TK1 is enabled to start sensing, and the cancellation circuit 422 will enable the operational amplifier 4224 to start to output a reference voltage signal VSf, i.e., the cancellation signal S3 in FIG. 4, according to the reference capacitance Cref. In addition, the subtractor circuit 4222 is configured to subtract the analog voltage signal VS1 output from the capacitor voltage converter 520 and the reference voltage signal VSf output from the operational amplifier 4224 to generate a subtraction result, and then provide the subtraction result to the ADC 124.

That is, the ADC 124 outputs the digital voltage signal VS2 according to the attenuated analog voltage signal VS1. It should be noted that the above-mentioned “subtraction result” can refer to a zero result or a non-zero result, but the present disclosure is not limited thereto. Therefore, the touch keyboard 4 in FIG. 5 can be programmed to design a magnitude of the reference capacitor Cref according to the sensing capacitance generated by the capacitive touch sensor TK1, so that the operational amplifier 4224 can output the reference voltage signal VSf greater than, less than, or even equal to the analog voltage signal VS1 according to the reference capacitor Cref.

On the other hand, if it is still considered that an effect of attenuation is achieved in a quantitative manner, in other embodiments, the magnitude of the reference capacitor Cref can be preset to be the same as the magnitude of the sensing capacitance of the capacitive touch sensor TK1 that is not pressed. In this way, when the capacitive touch sensor TK1 is not pressed and the driving signal is input to the input terminal IN of the capacitive touch sensor TK1, the touch keyboard 4 of FIG. 5 can use the reference voltage signal VSf output by the operational amplifier 4224 to completely cancel out the analog voltage signal VS1 output by the capacitor voltage converter 520, so that the ADC 124 will only receive the analog voltage signal VS1 that is zero.

Similarly, when the capacitive touch sensor TK1 is pressed, that is, the sensing capacitance is greater than a capacitance of the reference capacitor Cref, and the driving signal is input to the input terminal IN of the capacitive touch sensor TK1, the touch keyboard 4 of FIG. 5 can further use the reference voltage signal VSf output by the operational amplifier 4224 quantitatively and subtract the analog voltage signal VS1 output by the capacitor voltage converter 520, so that the ADC 124 outputs a corresponding digital voltage signal VS2 according to the attenuated analog voltage signal VS1. It is worth noting that the specific implementation of the above reference capacitor Cref is just an example, and it is not intended to limit the present disclosure. Those skilled in the art should be able to design the magnitude of the reference capacitor Cref according to actual needs or applications.

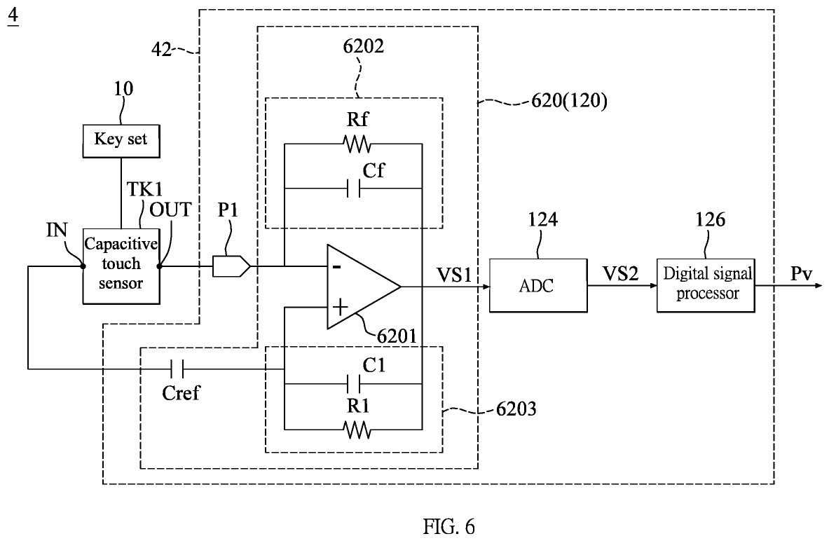

In addition, reference is made to FIG. 6, which is a schematic circuit diagram of the converter and the cancellation circuit of FIG. 4 according to a second preferred embodiment. Compared with the cancellation circuit 422 in FIG. 5, the cancellation circuit in FIG. 6 is directly integrated in the converter 120, that is, the capacitor voltage converter 620. Therefore, as shown in FIG. 6, the capacitor voltage converter 620 includes an operational amplifier 6201, a negative feedback circuit 6202, a positive feedback circuit 6203, and a reference capacitor Cref. An inverting input terminal of the operational amplifier 6201 is coupled to the input pin P 1, a non-inverting input terminal of the operational amplifier 6201 is coupled to the input terminal IN of the capacitive touch sensor TK1 through the reference capacitor Cref, and an output terminal of the operational amplifier 6201 is coupled to the ADC 124.

The negative feedback circuit 6202 is coupled between the inverting input terminal of the operational amplifier 6201 and the output terminal of the operational amplifier 6201, the negative feedback circuit 6202 is composed of a first capacitor Cf and a first resistor Rf connected in parallel with each other, the positive feedback circuit 6203 is coupled between the non-inverting input terminal of the operational amplifier 6201 and the output terminal of the operational amplifier 6201, and the positive feedback circuit 6203 is composed of a capacitor C1 and a resistor R1 connected in parallel with each other. However, since operating principles of the capacitor voltage converter 620 are already known to those skilled in the art, details related to the operational amplifier 6201, the negative feedback circuit 6202 and the positive feedback circuit 6203 will not be repeated here. It should be understood that the touch keyboard 4 in FIG. 6 can be programmed to design a magnitude of the reference capacitor Cref according to a magnitude of the sensing capacitance generated by the capacitive touch sensor TK1, so that the capacitor voltage converter 620 can output the attenuated analog voltage signal VS1 to the ADC 214 according to the reference capacitor Cref.

Similarly, if it is still considered that an effect of attenuation is achieved in a quantitative manner, in other embodiments, the magnitude of the reference capacitor Cref can be preset to be the same as the magnitude of the sensing capacitance of the capacitive touch sensor TK1 that is not pressed. In this way, when the capacitive touch sensor TK1 is not pressed and the driving signal (not shown in FIG. 6) is input to the input terminal IN of the capacitive touch sensor TK1, the touch keyboard 4 of FIG. 6 can use a capacitor voltage converter 620 to output the analog voltage signal VS1 being zero. Similarly, when the capacitive touch sensor TK1 is pressed, that is, the sensing capacitance is greater than a capacitance of the reference capacitor Cref, and the driving signal is input to the input terminal IN of the capacitive touch sensor TK1, the touch keyboard 4 of FIG. 6 can further use the capacitor voltage converter 620 to output the attenuated analog voltage signal VS1, such that the ADC 124 outputs the corresponding digital voltage signal VS2 according to the attenuated analog voltage signal VS1.

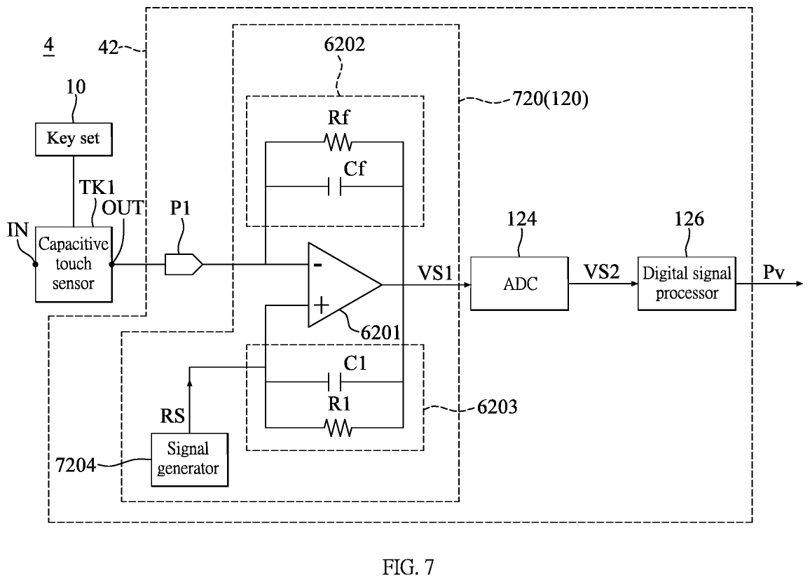

In addition, reference is made to FIG. 7, which is a circuit diagram of the converter 120 and the cancellation circuit 422 of FIG. 4 according to a third preferred embodiment, and some components in FIG. 7 that are the same as or similar to those in FIG. 6 are represented by the same or similar reference numerals, so the details are not described in detail. As shown in FIG. 7, the cancellation circuit of FIG. 7 is also directly integrated in the converter 120, that is, the capacitor-voltage converter 720, however, compared to the capacitor voltage converter 620 of FIG. 6, the capacitor voltage converter 720 of FIG. 7 uses the non-inverting input terminal of the operational amplifier 6201 to be directly coupled to a signal generator 7204. That is, the content of the reference signal RS generated by the signal generator 7204 is represented as the reference capacitor Cref of FIG. 6.

Similarly, if it is still considered that an effect of attenuation is achieved in a quantitative manner, in other embodiments, the magnitude of the reference signal RS generated by the signal generator 7204 can be preset to be the same as the magnitude of the sensing capacitance of the capacitive touch sensor TK1 that is not pressed. In this way, when the capacitive touch sensor TK1 is not pressed, and the driving signal (not shown in FIG. 7) is input to the input terminal IN of the capacitive touch sensor TK1, the touch keyboard 4 of FIG. 7 can use the capacitor voltage converter 720 to output the analog voltage signal VS1 being zero. When the capacitive touch sensor TK1 is pressed, that is, the sensing capacitance is larger than the magnitude of the reference signal RS, and the driving signal is input to the input terminal IN of the capacitive touch sensor TK1, the touch keyboard 4 in FIG. 7 can also use the capacitor voltage converter 720 to output the attenuated analog voltage signal VS1, so that the ADC 14 outputs corresponding digital voltage signal VS2 according to the attenuated analog voltage signal VS1.

In practice, the signal generator 7204 can be, for example, a digital-to-analog converter, but the present disclosure is not limited thereto. In summary, compared to the touch keyboards 1 of FIGS. 1 to 3, the touch keyboards 4 of FIGS. 4 to 7 are modified to attenuate the analog voltage signal VS1 through the cancellation circuit 422 or the capacitor voltage converter 620 or 721 before the analog voltage signal VS1 is input to the ADC 124, so that the ADC 124 outputs the digital voltage signal VS2 according to the attenuated analog voltage signal VS1. Since the details are as described above, the repeated descriptions are omitted here.

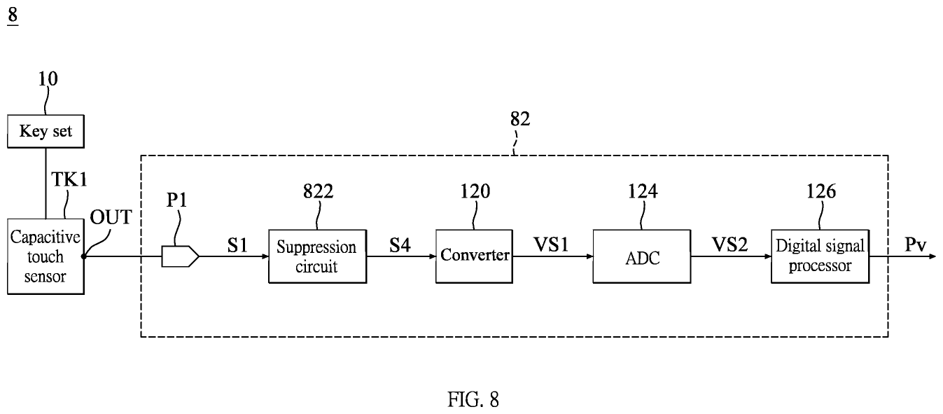

On the other hand, as mentioned above, the present disclosure does not limit the specific implementation of attenuating the sensing capacitance. Therefore, reference is made to FIG. 8, FIG. 8 is a functional block diagram of a touch keyboard according to a third embodiment of the present disclosure, and some components in FIG. 8 are the same as those in FIG. 1 are denoted by the same reference numerals, so the details are not described here. As shown in FIG. 8, compared to the pressure sensing circuit 12 of the touch keyboard 1 of FIG. 1, the pressure sensing circuit 82 of the touch keyboard 8 of FIG. 8 not only includes a converter 120, an analog-to-digital converter 124, and a digital signal processor 126, but also mainly includes a suppression circuit 822. Compared to the cancellation circuit 122 of FIG. 1, the cancellation circuit 122 performs a subtraction operation on the sensing signal S1, that is, the sensing capacitance, to eliminate a part of the sensing capacitance, but the suppression circuit 822 of FIG. 8 performs a division operation on the sensing signal S1, that is, the sensing capacitance, to proportionally reduce a magnitude of the sensing signal S1.

In detail, the suppression circuit 822 is coupled between the converter 120 and the input pin P1, and is configured to suppress the sensing signal S1, and then provide a suppressed sensing signal S4 to the converter 120, so that the converter outputs the analog voltage signal VS1 according to the suppressed sensing signal S4. It should be noted that a suppression degree for the sensing signal S1, that is, the sensing capacitance, suppressed by the suppression circuit 822, can be determined by a preset parameter, or determined according to the current operating environment of the pressure sensing circuit 82 (e.g., operating temperature, average sensing capacitance, and the like.) However, the present disclosure is not limited thereto.

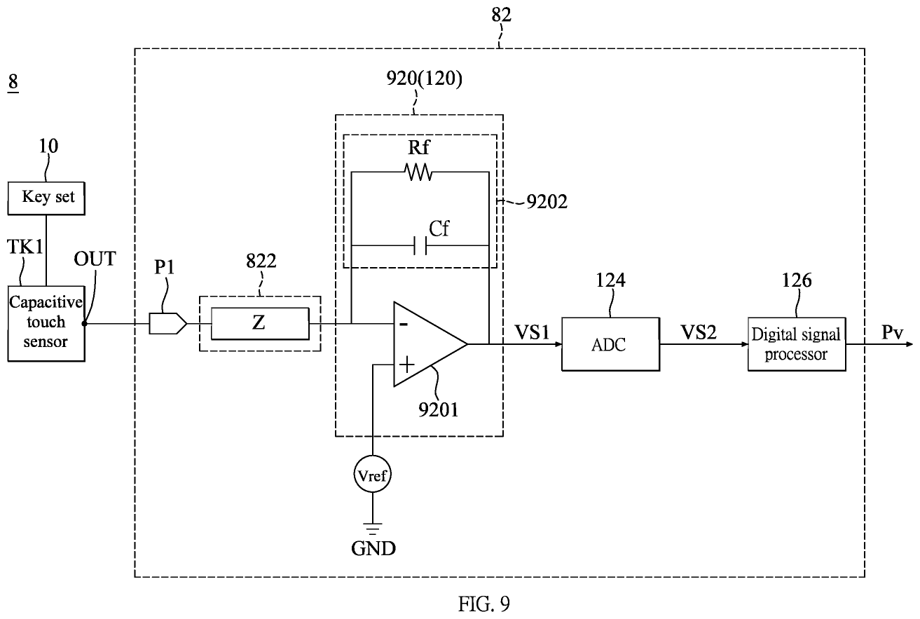

In addition, reference is made to FIG. 9, which is a schematic circuit diagram of the converter 120 and the suppression circuit 822 of FIG. 8 according to a first preferred embodiment. As shown in FIG. 9, the converter 120 can be, for example, a capacitor voltage converter 900, which includes an operational amplifier 9201 and a negative feedback circuit 9202. An inverting input terminal of the operational amplifier 9201 is coupled to the input pin P1 through the suppression circuit 822, a non-inverting input terminal of the operational amplifier 9201 is coupled to the reference voltage Vref, and an output terminal of the operational amplifier 9201 is coupled to the ADC 124. In addition, the negative feedback circuit 9202 is coupled between the inverting input terminal of the operational amplifier 9201 and the output terminal of the operational amplifier 9201, and the negative feedback circuit 9202 is composed of a first capacitor Cf and a first resistor Rf connected in parallel with each other. Since the details of the capacitor voltage converter 920 are as described above, the repeated descriptions are omitted here.

It should be understood that the suppression circuit 822 can be, for example, an impedance component Z, which is coupled between the inverting input terminal of the operational amplifier 9201 and the input pin P1. The impedance component Z is served as the preset parameter according to an impedance value of the impedance component Z, thereby suppressing the sensing capacitance generated by the capacitive touch sensor TK1, so that the capacitor voltage converter 920 outputs the analog voltage signal VS1 according to the suppressed sensing capacitance. Since principles of capacitance suppression performed by using the impedance component Z is already known to those skilled in the art, details thereof will not be repeated here.

It should also be understood that the impedance component Z can be composed of at least one passive component. That is, the impedance component Z can be not only a single resistor, a single capacitor, or a single inductor, but also any combination of the above passive components. In summary, the present disclosure does not limit the specific implementation of the impedance component Z. Those skilled in the art should be able to design the impedance component Z according to actual needs or applications. In addition, the impedance component Z can also be integrated in the capacitor voltage converter 920 or can be provided separately, but the present disclosure is not limited thereto. In any case, compared to the cancellation circuit 122 of FIG. 1, the suppression circuit 822 of FIG. 9 uses a division operation to perform an attenuation operation associated with the sensing capacitance. However, the manner in which the impedance component Z is used as the suppression circuit 822 is merely an example, which is not intended to limit the present disclosure.

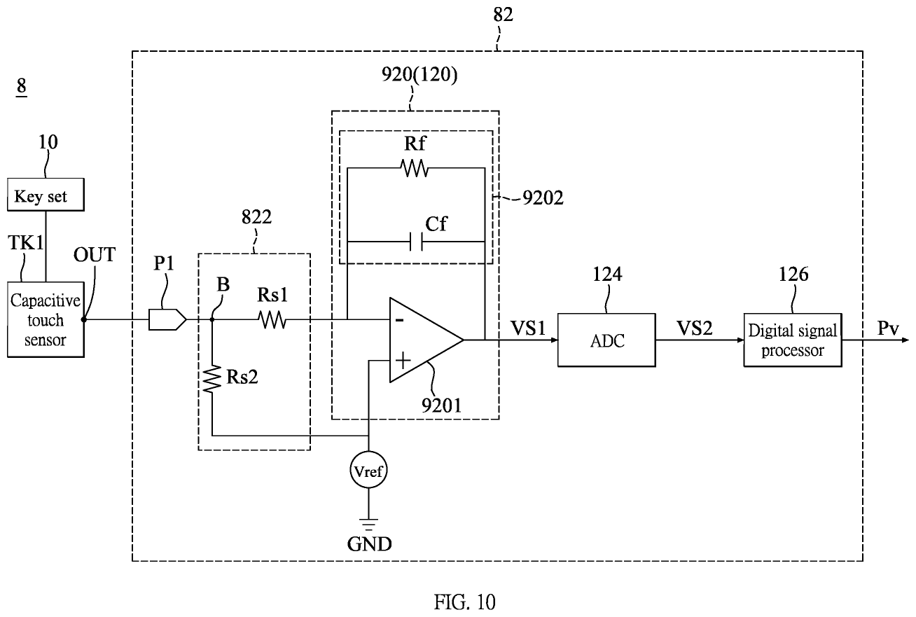

Reference is made to FIG. 10, which is a circuit diagram of the converter 120 and the suppression circuit 822 of FIG. 8 according to a second preferred embodiment. As shown in FIG. 10, the suppression circuit 822 can also be, for example, a voltage dividing circuit including a resistor Rs1 and a resistor Rs2. The resistor Rs1 is coupled between the inverting input terminal of the operational amplifier 9201 and the input pin P1. A first terminal of the resistor Rs2 is coupled to a node B between the resistor Rs1 and the input pin P1, and a second terminal of the resistor Rs2 is connected to the reference voltage Vref. It should be understood that the suppressing circuit 822 of FIG. 10 serves as the preset parameter according to an impedance ratio of the resistor Rs1 to the resistor Rs2, thereby suppressing the sensing capacitance generated by the capacitive touch sensor TK1, so that the capacitor voltage converter 920 outputs the analog voltage signal VS1 according to the suppressed sensing capacitance. Since the operation principles of the voltage dividing circuit is already known to those skilled in the art, details thereof will not be repeated here.

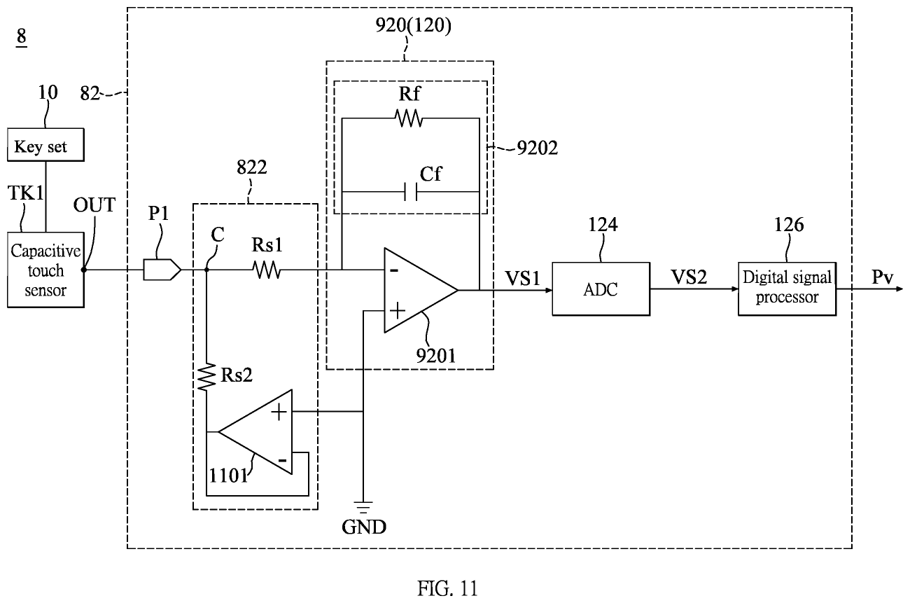

In addition, if it is further considered that the reference voltage Vref can be, for example, the ground voltage GND, reference is made to FIG. 11. FIG. 11 is a circuit diagram of the converter 120 and the suppression circuit 822 of FIG. 8 according to a third preferred embodiment, and some components in FIG. 11 that are the same as or similar to those in FIG. 10 are represented by the same reference numerals, so the details are not described in detail. As shown in FIG. 11, the suppression circuit 822 can include a resistor Rs1, a resistor Rs2, and an operational amplifier 1101. The resistor Rs1 is coupled between the inverting input terminal of the operational amplifier 9201 and the input pin P1. The non-inverting input terminal of the operational amplifier 1101 is coupled to the ground voltage GND, and the inverting input terminal of the operational amplifier 1101 is coupled to the output terminal of the operational amplifier 1101. In addition, the first terminal of the resistor Rs2 is coupled to a node C between the input pin P1 and the resistor Rs2, and the second terminal of the resistor Rs2 is coupled to the output terminal of the operational amplifier 1101. Since the operation principles of the suppression circuit 822 in FIG. 11 is also known to those skilled in the art, details thereof will not be repeated here.

In conclusion, the touch keyboard provided by the embodiments of the present disclosure does not need to introduce a complicated circuit design, but only needs a simple circuit design, such as the cancellation circuit or the suppression circuit, can cause the sensing capacitance generated by the capacitive touch sensor to be attenuated to avoid the capacitor voltage converter in the pressure sensing circuit from overflowing due to receiving an excessively large sensing capacitance, and it also means that a detection range is increased, making it possible to detect a larger sensing capacitance and improving the sensitivity of the touch keyboard.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A touch keyboard, comprising:
a key set;
a capacitive touch sensor coupled to the key set, configured to generate a sensing capacitance; and
a pressure sensing circuit coupled to the capacitive touch sensor, configured to generate a pressure sensing value, and including:
a converter coupled to an input pin, configured to receive a sensing signal provided from the input pin, and output an analog voltage signal;
a cancellation circuit coupled between the converter and the input pin, configured to generate a cancellation signal, and enable the converter to output the analog voltage signal according to the sensing signal that is added by the cancellation signal;
an analog-to-digital converter (ADC) coupled to the converter and configured to convert the analog voltage signal into a digital voltage signal; and
a digital signal processor coupled to the ADC and configured to generate the pressure sensing value corresponding to the sensing signal according to the digital voltage signal.

2. The touch keyboard according to claim 1, wherein a content of the sensing signal is the sensing capacitance generated by the capacitive touch sensor, and the input pin is used to couple the pressure sensing circuit to an output terminal of the capacitive touch sensor.

3. The touch keyboard according to claim 2, wherein the converter is a capacitor voltage converter, which includes:
an operational amplifier having an inverting input terminal coupled to a node between the input pin and the cancellation circuit, a non-inverting input terminal coupled to a ground voltage, and an output terminal coupled to the analog-to-digital converter; and
a negative feedback circuit coupled between the inverting input terminal of the operational amplifier and the output terminal of the operational amplifier, wherein the negative feedback circuit is composed of a first capacitor and a first switch connected in parallel with each other, and the first switch is controlled by a first control signal to be turned on or off.

4. The touch keyboard according to claim 3, wherein the pressure sensing circuit further includes:
a second switch coupled between the input pin and the node, and controlled by a second control signal to be turned on or off; and
a third switch coupled between the input pin and the ground voltage, and controlled by the first control signal to be turned on or off;
wherein the first switch and the third switch are controlled to be turned on simultaneously by the first control signal, and on-times of the first switch and the third switch controlled by the first control signal are staggered with on-times of the second switch controlled by the second control signal.

5. The touch keyboard according to claim 4, wherein the cancellation circuit is a branch connection, which is coupled between the node and the ground voltage, and is configured to reduce the sensing capacitance generated by the capacitive touch sensor, and enable the capacitor voltage converter to output the analog voltage signal according to the reduced sensing capacitance.

6. The touch keyboard according to claim 5, wherein the branch connection includes:
a constant current source circuit, configured to, in response to the second control signal controlling the second switch to be turned on, attenuate the sensing capacitance generated by the capacitive touch sensor according to a preset parameter to enable the capacitor voltage converter to output the analog voltage signal according to the attenuated sensing capacitance.

7. The touch keyboard according to claim 2, wherein the cancellation circuit includes:
a signal generator configured to generate the cancellation signal, wherein a polarity of the cancellation signal generated by the signal generator is opposite to a polarity of the sensing capacitance generated by the capacitive touch sensor; and
an adder circuit configured to add the sensing capacitance generated by the capacitive touch sensor to the cancellation signal, and then provide the sensing capacitance added with the cancellation signal to the converter.

8. The touch keyboard according to claim 7, wherein the converter is a capacitor voltage converter, which includes:
an operational amplifier having an inverting input terminal coupled to the input pin through the adder circuit, a non-inverting input terminal coupled to a reference voltage, and an output terminal coupled to the analog-to-digital converter; and
a negative feedback circuit coupled between the inverting input terminal of the operational amplifier and the output terminal of the operational amplifier, wherein the negative feedback circuit is composed of a first capacitor and a first resistor connected in parallel with each other.

9. A touch keyboard, comprising:
a key set;
a capacitive touch sensor coupled to the key set, configured to generate a sensing capacitance; and
a pressure sensing circuit is coupled to the capacitive touch sensor, configured to generate a pressure sensing value, and including:
a converter coupled to an input pin, configured to receive a sensing signal provided from the input pin, and output an analog voltage signal;
an analog-to-digital converter (ADC) coupled to the converter and configured to convert the analog voltage signal into a digital voltage signal;
a cancellation circuit coupled between the converter and the ADC, configured to generate a cancellation signal, and enable the ADC to output the digital voltage signal according to the analog voltage signal that is subtracted by the cancellation signal; and
a digital signal processor coupled to the ADC and configured to generate the pressure sensing value corresponding to the sensing signal according to the digital voltage signal.

10. The touch keyboard according to claim 9, wherein a content of the sensing signal is the sensing capacitance generated by the capacitive touch sensor, and the input pin is used to couple the pressure sensing circuit to an output terminal of the capacitive touch sensor.

11. The touch keyboard according to claim 10, wherein the converter is a capacitor voltage converter, which includes:
a first operational amplifier having an inverting input terminal coupled to the input pin, a non-inverting input terminal coupled to a ground voltage, and an output terminal coupled to the ADC; and
a first negative feedback circuit coupled between the inverting input terminal of the first operational amplifier and the output terminal of the first operational amplifier, wherein the first negative feedback circuit is composed of a first capacitor and a first resistor connected in parallel with each other.

12. The touch keyboard according to claim 11, wherein the cancellation circuit includes:
a subtractor circuit coupled between the output terminal of the first operational amplifier and the ADC;
a second operational amplifier having an inverting input terminal coupled to an input terminal of the capacitive touch sensor, a non-inverting input terminal coupled to the ground voltage, and an output terminal coupled to the subtractor circuit;
a second negative feedback circuit coupled between the inverting input terminal of the second operational amplifier and the output terminal of the second operational amplifier, wherein the second negative feedback circuit is composed of a second capacitor and a second resistor connected in parallel with each other; and
a reference capacitor coupled between the inverting input terminal of the second operational amplifier and the input terminal of the capacitive touch sensor.

13. The touch keyboard according to claim 12, wherein the second operational amplifier, the second negative feedback circuit, the reference capacitor, and the capacitor voltage converter are disposed on the same chip substrate, and in response to a driving signal being input to the input terminal of the capacitive touch sensor, the second operational amplifier is configured to start outputting a reference voltage signal according to the reference capacitance, and the subtractor circuit is configured to enable the analog voltage signal output by the capacitor voltage converter to be subtracted from the reference voltage signal output by the second operational amplifier to generate a subtraction result, and provide the subtraction result to the ADC.

14. The touch keyboard according to claim 10, wherein the cancellation circuit is integrated in the converter, and the converter is a capacitor voltage converter, including:
an operational amplifier having an inverting input terminal coupled to the input pin, a non-inverting input terminal coupled to an input terminal of the capacitive touch sensor, and an output terminal coupled to the ADC; and
a negative feedback circuit coupled between the inverting input terminal of the operational amplifier and the output terminal of the operational amplifier, wherein the negative feedback circuit is composed of a first capacitor and a first resistor connected in parallel with each other.

15. The touch keyboard according to claim 14, wherein the capacitor voltage converter further includes:
a positive feedback circuit coupled between the non-inverting input terminal of the operational amplifier and the output terminal of the operational amplifier, wherein the positive feedback circuit is composed of a second capacitor and a second resistor connected in parallel with each other; and
a reference capacitor coupled between the inverting input terminal of the operational amplifier and the input terminal of the capacitive touch sensor.

16. The touch keyboard according to claim 10, wherein the cancellation circuit is integrated in the converter, and the converter is a capacitor voltage converter, including:
an operational amplifier having an inverting input terminal coupled to the input pin, a non-inverting input terminal coupled to a signal generator, and an output terminal coupled to the ADC;
a negative feedback circuit coupled between the inverting input terminal of the operational amplifier and the output terminal of the operational amplifier, wherein the negative feedback circuit is composed of a first capacitor and a first resistor connected in parallel with each other; and
a positive feedback circuit coupled between the non-inverting input terminal of the operational amplifier and the output terminal of the operational amplifier, wherein the positive feedback circuit is composed of a second capacitor and a second resistor connected in parallel with each other.

17. A touch keyboard, comprising:
a key set;
a capacitive touch sensor coupled to the key set, configured to generate a sensing capacitance; and
a pressure sensing circuit coupled to the capacitive touch sensor, configured to generate a pressure sensing value, and including:
a converter coupled to an input pin, configured to receive a sensing signal provided from the input pin, and output an analog voltage signal;
a suppression circuit coupled between the converter and the input pin, configured to suppress the sensing signal according to a preset parameter, then provide the suppressed sensing signal to the converter, and enable the converter to output the analog voltage signal according to the suppressed sensing signal;
an analog-to-digital converter (ADC) coupled to the converter and configured to convert the analog voltage signal into a digital voltage signal; and
a digital signal processor coupled to the ADC and configured to generate the pressure sensing value corresponding to the sensing signal according to the digital voltage signal.

18. The touch keyboard according to claim 17, wherein a content of the sensing signal is the sensing capacitance generated by the capacitive touch sensor, and the input pin is used to couple the pressure sensing circuit to an output terminal of the capacitive touch sensor.

19. The touch keyboard according to claim 18, wherein the converter is a capacitor voltage converter, which includes:
an operational amplifier having an inverting input terminal coupled to the input pin through the suppression circuit, a non-inverting input terminal coupled to a reference voltage, and an output terminal coupled to the ADC; and
a negative feedback circuit coupled between the inverting input terminal of the first operational amplifier and the output terminal of the first operational amplifier, wherein the negative feedback circuit is composed of a first capacitor and a first resistor connected in parallel with each other.

20. The touch keyboard according to claim 19, wherein the suppression circuit is an impedance component coupled between the inverting input terminal of the first operational amplifier and the input pin, wherein the impedance component is configured to use an impedance value of the impedance component as the preset parameter to suppress the sensing capacitance generated by the capacitive touch sensor, and enable the capacitive voltage converter to output the analog voltage signal according to the suppressed sensing capacitance.

21. The touch keyboard according to claim 20, wherein the impedance component is composed of at least one passive component.

22. The touch keyboard according to claim 19, wherein the suppression circuit is a voltage dividing circuit including a second resistor and a third resistor, wherein the second resistor is coupled between the inverting input terminal of the first operational amplifier and the input pin, a first terminal of the third resistor is coupled to a node between the second resistor and the input pin, and a second terminal of the third resistor is coupled to the reference voltage.

23. The touch keyboard according to claim 19, wherein in response to the reference voltage being a ground voltage, the suppression circuit includes:
a second resistor coupled between the inverting input terminal of the first operational amplifier and the input pin;
a second operational amplifier having a non-inverting input terminal coupled to the ground voltage, and an inverting input terminal coupled to an output terminal of the second operational amplifier; and
a third resistor having a first terminal coupled to a node between the input pin and the second resistor, and a second terminal coupled to the output terminal of the second operational amplifier.

24. A touch keyboard, comprising:
a key set;
a capacitive touch sensor coupled to the key set, configured to generate a sensing capacitance; and
a pressure sensing circuit is coupled to the capacitive touch sensor, configured to generate a pressure sensing value, and including:
a converter coupled to an input pin, configured to receive a capacitance sensing signal provided from the input pin and output a circuit signal corresponding to a pressure value sensed by the capacitance sensing signal; and
a cancellation circuit coupled between the converter and the input pin, configured to generate a cancellation signal, and enable the converter to output the circuit signal according to the capacitance sensing signal being added with the cancellation signal.

25. The touch keyboard according to claim 24, wherein the circuit signal is a voltage signal, and a voltage value of the voltage signal is proportional to the pressure value sensed by the capacitance sensing signal.

26. The touch keyboard according to claim 25, wherein the voltage signal is an analog voltage signal, and the converter is further coupled to an analog-to-digital converter and configured to convert the analog voltage signal into a digital voltage signal.

27. The touch keyboard according to claim 26, wherein the pressure sensing circuit further includes a digital signal processor coupled to the ADC, and configured to generate the pressure sensing value corresponding to the capacitance sensing signal according to the digital voltage signal.
